(19) United States
(12) Patent Application Publication
(10) Pub. No.: US 2011/0316050 A1
(43) Pub. Date: Dec. 29, 2011

(54) SEMICONDUCTOR DEVICE HAVING A HETEROJUNCTION BIOPOLAR TRANSISTOR AND A FIELD EFFECT TRANSISTOR

(75) Inventor: YASUNORI BITO, KANAGAWA (JP)

(73) Assignee: RENESAS ELECTRONICS CORPORATION, KANAGAWA (JP)

(21) Appl. No.: 13/166,127

(22) Filed: Jun. 22, 2011

(30) Foreign Application Priority Data
Jun. 24, 2010 (JP) 2010-143647

(51) Int. Cl. H01L 27/06

(52) U.S. Cl. 257/197; 257/E27.015

(57) ABSTRACT

A semiconductor device with a heterojunction bipolar transistor (HBT) and a field effect transistor (FET) formed over the same substrate; providing improved HBT characteristics and a lowered HBT collector resistance and also satisfactory etching of the FET gate recess, along with low ON-resistance in the FET. The sub-collector layer of a heterojunction bipolar transistor (HBT) is a laminated structure of multiple semiconductor layers, and moreover with a collector electrode formed on a section projecting out from one collector layer. In two of the FET, at least one semiconductor layer on the semiconductor substrate side of the semiconductor layers forming the sub-collector layer of the HBT also serves as at least a portion of a capacitor layer. The total film thickness of the HBT sub-collector layer is 500 nm or more; and the total film thickness of the FET capacitor layer is between 50 nm and 300 nm.

### CROSS-REFERENCE TO RELATED APPLICATIONS

The disclosure of Japanese Patent Application No. 2010-143647 filed on Jun. 24, 2010 including the specification, drawings and abstract is incorporated herein by reference in its entirety.

### BACKGROUND

The present invention relates to a semiconductor device with a heterojunction bipolar transistor (HBT) and a field effect transistor (FET) formed over the same substrate.

Semiconductor devices must become more highly integrated as RF modules for wireless terminals become ever smaller and acquire more functions. Semiconductor devices including RF power amp functions and RF switching functions formed on the same substrate are especially needed. Heterojunction bipolar transistors (HBT) are widely utilized as power amplifier elements in the related art. However the offset voltages in HBT makes them unsuited for implementing low-loss RF switches so the field effect transistor (FET) is typically utilized as the RF switching IC. Due to these circumstances, efforts are being made to develop a BiFET device with an HBT and FET formed over the same semiconductor substrate, to serve as a semiconductor device capable of implementing both power amplifier functions and switching IC functions on a single semiconductor device.

U.S. Pat. No. 7,015,519 specification of FIG. 5 discloses a BiFET device comprising a laminated epitaxial layer (102) including a buffer layer and a FET layer, an InGaP etching stopper layer (103), an n⁺-GaAs cap layer (104) serving as an HBT sub-collector layer and a FET cap layer, an InGaP etching stopper layer (124), a GaAs collector layer (105), a p⁺-GaAs base layer (106), an InGaP emitter layer (107), and an emitter contact layer (108) comprised of n⁺-GaAs and n⁺-InGaAs formed as a laminated epitaxial wafer over the semiconductor GaAs substrate; and an emitter electrode (112), a base electrode (115) a collector electrode (118), a source electrode (132), a drain electrode (134), and a gate electrode (138) are formed over that sequentially laminated epitaxial layer; and insulating regions (130) are further formed to electrically isolate the HBT and the FET.

In the BiFET device disclosed in U.S. Pat. No. 7,015,519 specification the n⁺-GaAs cap layer (104) serves as both the cap layer for the FET and the sub-collector for the HBT. The collector electrode (118) for the HBT and the ohmic electrodes (132, 134) for the FET are formed on the same surface of this (cap) layer.

Japanese patent laid-open No. 2009-224407 of FIG. 1B discloses a BiFET device comprising a buffer layer (102) comprised of a GaAs/AlGaAs superlattice layer, an AlGaAs barrier layer (103), an InGaAs channel layer (104), an electron supply layer (506), an n⁺-GaAs layer (107a) serving as the cap layer and the external sub-collector layer, an InGaP etching stopper layer (106), a GaAs internal sub-collector layer (107b), a GaAs collector layer (108), a GaAs base layer (109), an InGaP emitter layer (110), a GaAs emitter gap layer (111), and an InGaAs emitter contact layer (112) formed as a laminated epitaxial wafer over the semiconductor GaAs substrate (101); and an emitter electrode (201), a base electrode (202), a collector electrode (203), a source electrode (304), a drain electrode (305), and a gate electrode (306) formed over the laminated epitaxial wafer; and insulating regions (820) are further formed to electrically isolate the HBT and the FET.

In the structure of Japanese patent laid-open No. 2009-224407, the HBT collector electrode (203) and the FET ohmic electrodes (304, 305) are formed on the external sub-collector layer (107a) serving as the FET cap layer the same as in U.S. Pat. No. 7,015,519 specification.

In Japanese patent laid-open No. 2009-224407, by forming the HBT sub-collector layers as a laminated structure of an external sub-collector layer (107a) serving as the FET cap layer and a comparatively thick internal sub-collector layer (107b) not serving as the FET cap layer, the etching precision of the gate recess can be maintained without making the FET cap layer thicker, and a low resistance sub-collector layer can be made by increasing the overall thickness of the sub-collector layer. FIGS. 2A and 2B of Japanese patent laid-open No. 2009-224407, show an internal sub-collector resistance (RC2) that is greatly reduced compared to the resistance in the structure in U.S. Pat. No. 7,015,519 specification.

In the working example in Japanese patent laid-open No. 2009-224407, the thickness of the external sub-collector layer (107a) is 200 nm, and the thickness of the internal sub-collector layer (107b) is 400 nm (paragraph 0023). In paragraph 0038 in Japanese patent laid-open No. 2009-224407, the thickness of the external sub-collector layer (107a) is preferably 50 to 300 nm, and the thickness of the internal sub-collector layer (107b) is preferably 300 nm or more.

FIG. 3 of US Patent Application Publication No. 2007-2778523 laid-open discloses a BiFET device structure in which the sub-collector layer below the HBT collector electrode is a laminated structure including both a sub-collector layer (layer of reference numeral 118 of FIG. 1) also serving as the FET cap layer, and a sub-collector layer (layer of reference numeral 121 of FIG. 1) not serving as the FET cap layer, and the film thickness of this laminated structure is thicker than the cap layer below the FET ohmic electrode.

In US Patent Application Publication No. 2007-2778523 laid-open, FIG. 3 shows the fabrication of the BiFET device in the process shown in FIG. 2 utilizing the epitaxial wafer disclosed in FIG. 1 as a laminated structure including a buffer layer (111), an n-AlGaAs doping layer (112), an i-AlGaAs spacer layer (113), an InGaAs channel layer (114) an i-AlGaAs spacer layer (115), an n-AlGaAs doping layer (116), an i-AlGaAs barrier layer (117), an i-InGaP etching stopper layer (119), an n⁺-GaAs cap layer (118), an n⁺-InGaP etching stopper layer (104), an n⁺-GaAs sub-collector layer (121), an n-GaAs collector layer (122), a p⁺-GaAs base layer (123), an n-InGaP emitter layer (124), an n-GaAs emitter layer (125), and an n⁺-InGaAs emitter contact layer (126) that are formed over the semiconductor GaAs substrate (101).

### SUMMARY

The present inventor has now discovered the following problems in the structures disclosed in the U.S. Pat. No. 7,015,519, Japanese patent laid-open No. 2009-224407, and US Patent Application Publication No. 2007-2778523 laid-open. In the structure disclosed in U.S. Pat. No. 7,015,519 specification, making the n⁺-GaAs cap layer (104) that serves as the HBT sub-collector layer and FET cap layer thicker, reduces the collector resistance to improve the HBT characteristics but the layer to be etched away when forming the FET gate recess (136) is so thick that the gate recess etching precision deteriorates and the dimensional precision becomes worse (lines 23-30, fourth column). Namely, in the structure disclosed in U.S. Pat. No. 7,015,519 specification, lowering the collector resistance and accurate etching of the gate recess are opposing characteristics and achieving a balance between these characteristics is difficult. Therefore, even though the structure disclosed in U.S. Pat. No. 7,015,519 specification acts to lower the collector resistance in the HBT sub-collector layer, and improve the HBT characteristics, there is a limit to the thickness of the sub-collector layer (104). The film thickness of the n⁺-GaAs cap layer (104) is 350 nm in FIG. 3 for U.S. Pat. No. 7,015,519 specification and making a higher film thickness proves difficult.

In the structure disclosed in Japanese patent laid-open No. 2009-224407, the collector electrode (203) is formed over the external sub-collector layer (107a) the same as in U.S. Pat. No. 7,015,519 specification. Making the film thickness of the sub-collector layer below the collector electrode (203) thicker than 300 nm is difficult in view of the required gate recess etching precision of the FET. Examining FIGS. 2A and 2B of Japanese patent laid-open No. 2009-224407 reveals that though the structure in Japanese patent laid-open No. 2009-224407 has lower resistance in the sub-collector layer than in U.S. Pat. No. 7,015,519 specification, the collector resistance is still not low enough. In FIGS. 2A and 2B of Japanese patent laid-open No. 2009-224407, the resistance component (RC2+RC3) caused by the external sub-collector layer (107b) takes up approximately 60 percent of the total, showing that the resistance in this section is not sufficiently low.

The technology in US Patent Application Publication No. 2007-2778523 laid-open however provides no specific description of the HBT sub-collector layer thickness and the FET cap layer thickness, the preferred range of these layers is not clear, and there is no disclosure of design conditions for improving the characteristics of an HBT by lowering collector resistance, and for a satisfactory FET gate recess etching precision. Further, the film thickness of the cap layer below the FET ohmic electrode applies an effect to the FET ON-resistance but the preferred range for the film thickness of the cap layer is not described for that effect. The technology disclosed in US Patent Application Publication No. 2007-2778523 laid-open therefore cannot provide improved HBT characteristics by reducing the HBT collector resistance and cannot provide a stable BiFET device with low FET ON-resistance that also has satisfactory FET gate recess etching precision.

According to one aspect of the present invention, a semiconductor device includes: a heterojunction bipolar transistor including at least a first conductive type sub-collector layer, a collector layer, a second conductive type base layer, a first conductive type emitter layer, a collector electrode, a base electrode, an emitter electrode; and a field effect transistor including a channel layer to accumulate first conductive type carriers, a cap layer, a gate electrode, a pair of ohmic electrodes formed on the cap layer; with the heterojunction bipolar transistor and field effect transistor formed over different regions of the same semiconductor substrate, and in which in the heterojunction bipolar transistor, the sub-collector layer is comprised of a laminated structure including multiple first conductive type semiconductor layers and further the surface area of the sub-collector layer is larger than the collector layer, and in the sub-collector layer, the collector electrode is formed over a section protruding from the collector layer; and in the field effect transistor at least one semiconductor layer among the first conductive type semiconductor layers on the semiconductor substrate side that form the sub-collector layer of the heterojunction bipolar transistor also serves as at least a portion of the cap layer, and the total film thickness of the sub-collector layer in the heterojunction bipolar transistor is 500 nm or more, and the total film thickness of the cap layer in the field effect transistor is between 50 nm and 300 nm.

According to the aspect of the present invention, the semiconductor device containing both the HBT and FET on the same substrate, clarifies the preferred film thickness range of the HBT sub-collector layer and the FET cap layer, and is moreover capable of providing a stable semiconductor device with improved HBT characteristics at a low HBT collector resistance, and also satisfactory FET gate recess etching precision along with low FET ON-resistance. A detailed description is related later on however, the preferred range of the film thickness was derived by the present inventors based on the data shown in Tables 1 through Table 2, and FIG. 15 and FIG. 16.

The present invention with the HBT and FET formed over the same substrate is capable of providing a stable semiconductor device with improved HBT characteristics at a lower HBT collector resistance, and moreover satisfactory FET gate recess etching precision along with low FET ON-resistance.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a drawing showing a cross sectional view of the BiFET device of the first embodiment of this invention;

FIG. 2A is a manufacturing process view of the BiFET device of FIG. 1;

FIG. 2B is a manufacturing process view of the BiFET device of FIG. 1;

FIG. 2C is a manufacturing process view of the BiFET device of FIG. 1;

FIG. 2D is a manufacturing process view of the BiFET device of FIG. 1;

FIG. 2E is a manufacturing process view of the BiFET device of FIG. 1;

FIG. 2F is a manufacturing process view of the BiFET device of FIG. 1;

FIG. 2G is a manufacturing process view of the BiFET device of FIG. 1;

FIG. 2H is a manufacturing process view of the BiFET device of FIG. 1;

FIG. 3 is a drawing showing a cross sectional view of the BiFET device of the second embodiment of this invention;

FIG. 4 is a drawing showing a cross sectional view of the BiFET device of the third embodiment of this invention;

FIG. 5 is a drawing showing a cross sectional view of the BiFET device of the fourth embodiment of this invention;

FIG. 6 is a drawing showing a cross sectional view of the BiFET device of the fifth embodiment of this invention;

FIG. 7 is a drawing showing a cross sectional view of the BiFET device of the sixth embodiment of this invention;

FIG. 8 is a drawing showing a cross sectional view of the BiFET device of the seventh embodiment of this invention;

FIG. 9 is a drawing showing a cross sectional view of the BiFET device of the eighth embodiment of this invention;

FIG. 10 is a drawing showing a cross sectional view of the BiFET device of the ninth embodiment of this invention;

FIG. 11 is a drawing showing a cross sectional view of the BiFET device of the tenth embodiment of this invention;

FIG. 12 is a drawing showing a cross sectional view of the BiFET device of the eleventh embodiment of this invention;

FIG. 13 is a drawing showing a cross sectional view of the BiFET device of the twelfth embodiment of this invention;

FIG. 14 is a drawing showing a cross sectional view of the BiFET device of the thirteenth embodiment of this invention;

FIG. 15 is a graph showing the relation between the total film thickness of the HBT sub-collector and the HBT characteristics; and

FIG. 16 is a graph showing the inter-relation among the total film thickness of the FET cap layer and the gate recess etching precision (variation), and the FET characteristics.

### DETAILED DESCRIPTION

### First Embodiment

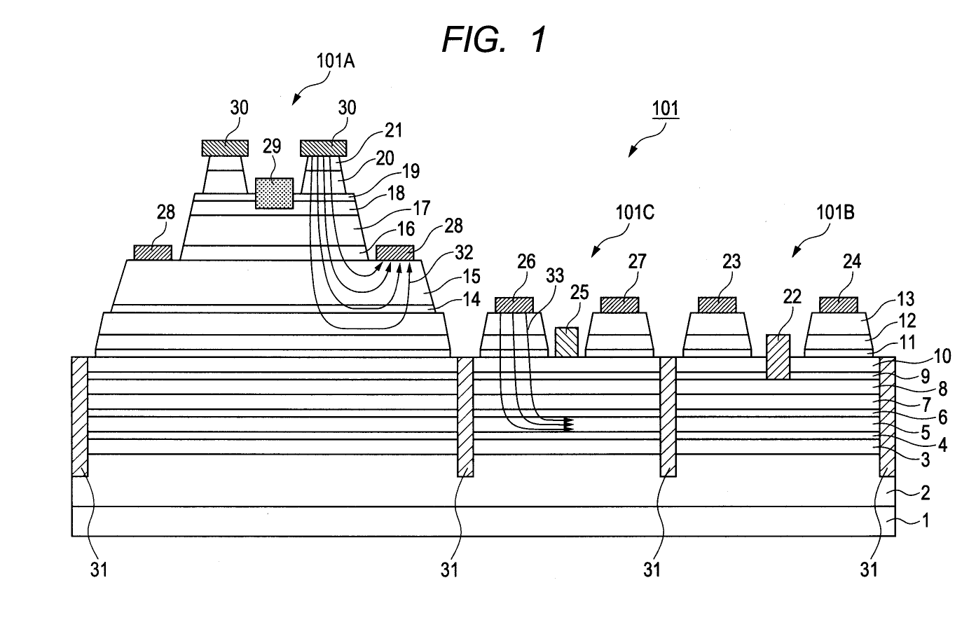

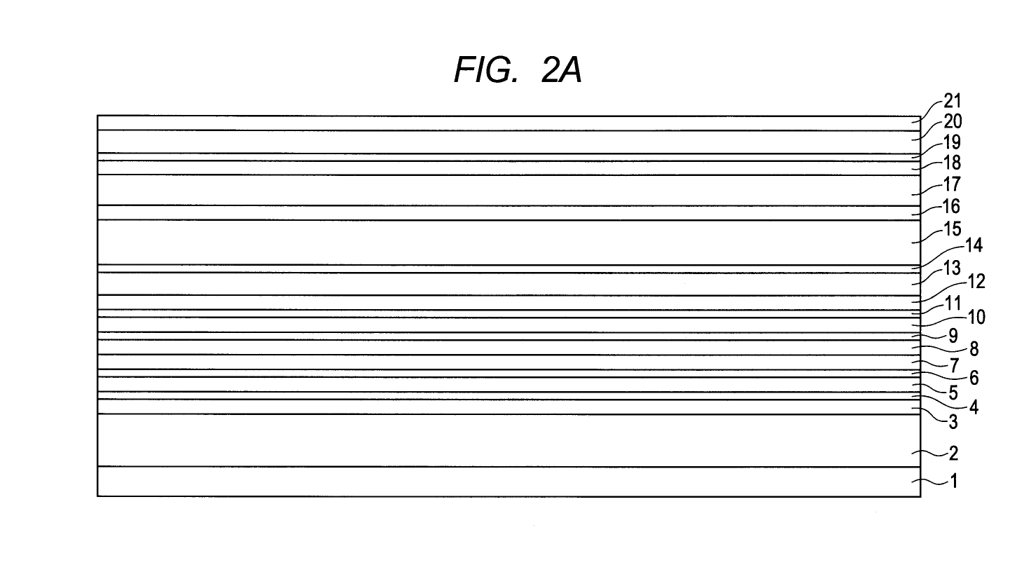

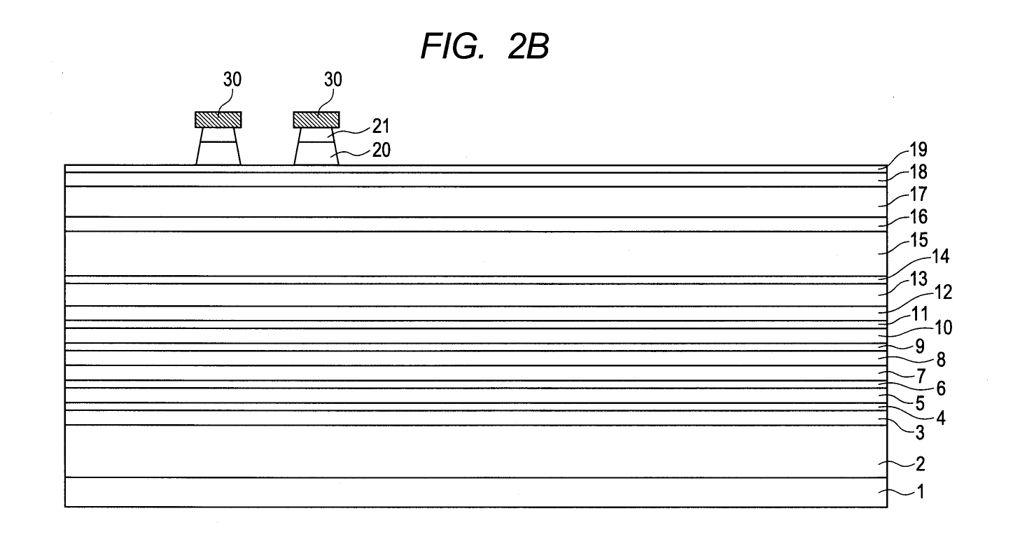

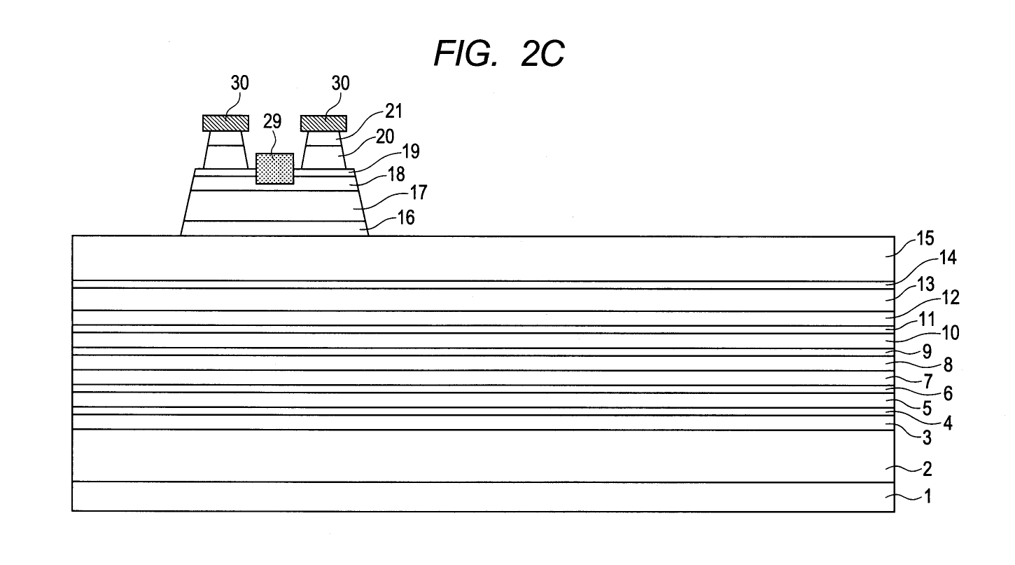

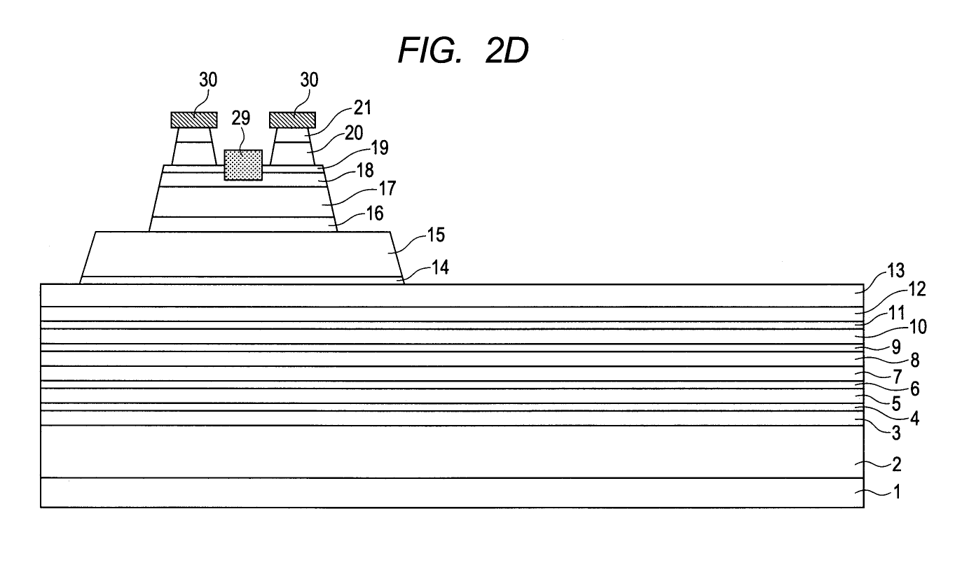

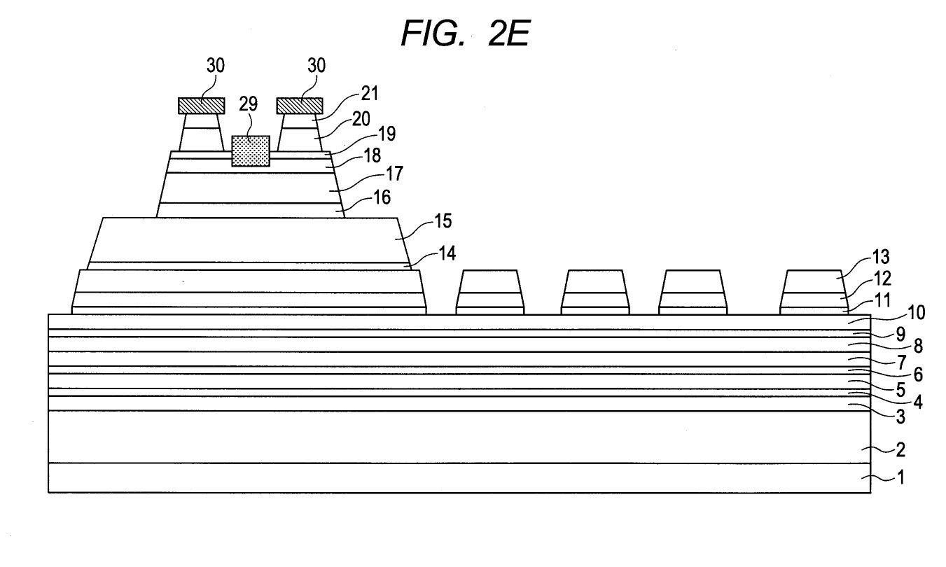

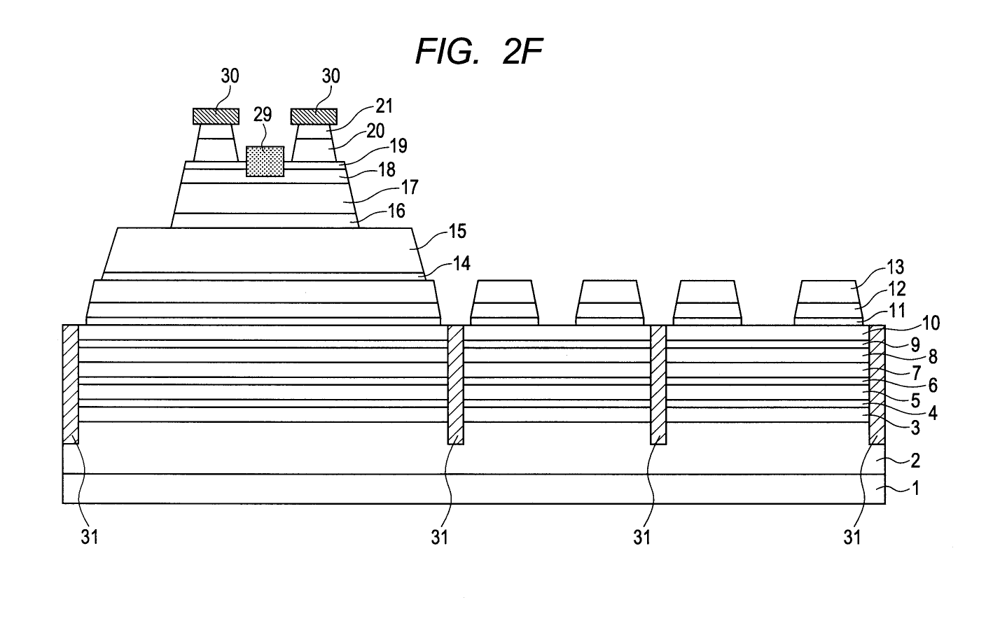

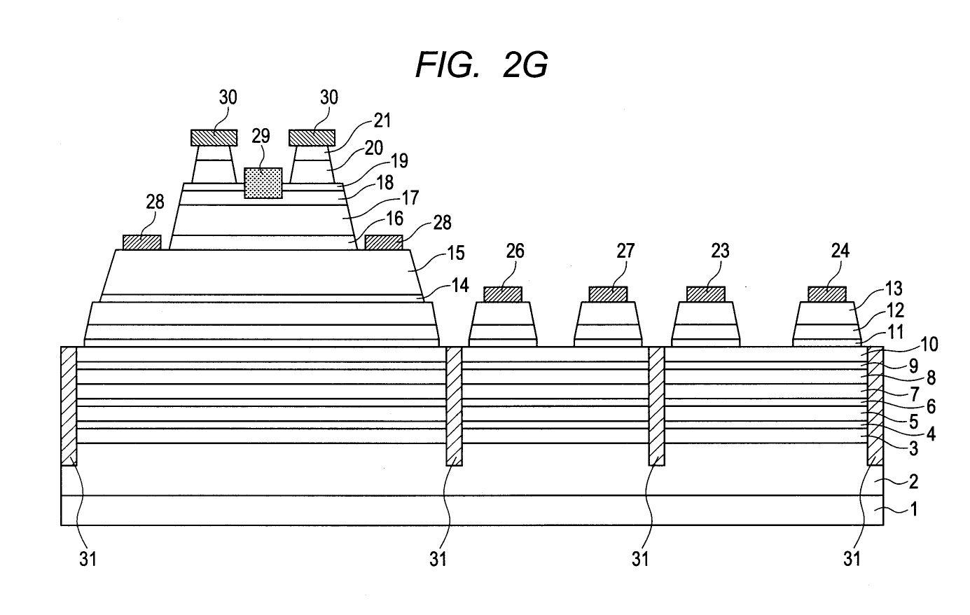

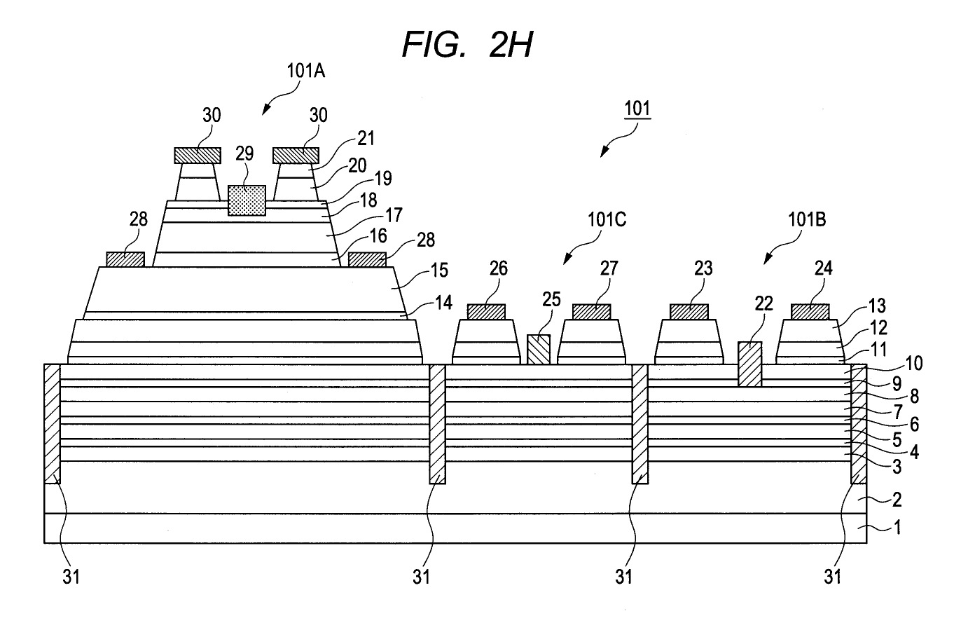

The structure and method for manufacturing the semiconductor device and production method of the first embodiment of this invention are described next while referring to the drawings. FIG. 1 is a cross sectional view of the semiconductor device. FIG. 2A through FIG. 2H are manufacturing process views. The reduction scale and position of each structural element are changed as convenient to make viewing and recognizing the drawings easier and are different from the actual elements. Hatching is omitted as convenient from the cross sectional views. The substrate, semiconductor layer, and the film thickness and composition of the electrodes, the impurity concentration in the semiconductor layer, and the semiconductor layer laminated structure are examples and design changes can be made as needed. Changes may also be made in the other embodiments.

A semiconductor device 101 of this embodiment as shown in FIG. 1 is a BiFET device comprised of one heterojunction bipolar transistor (HBT) 101A, and two field effect transistors (FET) 101B and 101C possessing different threshold voltages and formed on different regions on the same semiconductor substrate 1. In this embodiment, the FET 101B is an enhancement-mode FET (E-FET) and the FET 101C is a depletion-mode FET (D-FET). The semiconductor device 101 of this embodiment is preferably utilized in power amplifier IC and power amplifier modules for wireless terminals.

The HBT 101A is comprised of a first conductive type sub-collector layer, a first conductive type collector layer, a second conductive type base layer, a first conductive type emitter layer, a collector electrode, a base electrode and an emitter electrode. The FET 101B and 101C include a pair of ohmic electrodes formed over the cap layer, the gate electrode, the cap electrode and the channel layer to accumulate the first conductive type carriers. The example in this embodiment is utilized to describe the case where the first conductive type is the n type, and the second conductive type is the p type, however opposite type conduction may also be utilized.

The HBT 101A and the FET 101B and 101C jointly share the semiconductor substrate 1 and the semiconductor layers 2 through 13 laminated over that substrate.

Characteristics such as the composition and film thickness of the semiconductor substrate 1 and the semiconductor layers 2 through 13 laminated in sequence over that substrate are as follows. 1: semiconductor GaAs substrate, 2: undoped laminated buffer layer with 500 nm film thickness, 3: n⁺-AlGaAs lower electron supply layer with 4 nm film thickness and doping of 3.0×10¹⁸ cm⁻³ silicon impurities, 4: undoped AlGaAs spacer layer with 2 nm film thickness, 5: undoped InGaAs channel layer with 15 nm film thickness, 6: undoped AlGaAs spacer layer with 2 nm film thickness, 7: n⁺-AlGaAs upper electron supply layer with 10 nm film thickness and doping of 3.0×10¹⁸ cm⁻³ silicon impurities, 8: undoped AlGaAs Schottky layer with 5 nm film thickness, 9: undoped InGaP stopper layer with 5 nm film thickness, 10: undoped AlGaAs Schottky layer with 25 nm film thickness, 11: undoped InGaP etching stopper layer with 15 nm film thickness, 12: n-GaAs cap layer with 50 nm film thickness and doping of 4.0×10¹⁷ cm⁻³ silicon impurities, 13: n⁺-GaAs lower sub-collector layer and cap layer with 150 nm film thickness and doping of 4.0×10¹⁸ cm⁻³ silicon impurities.

The insulating regions 31 are formed among the HBT 101A, the FET 101B, and FET 101C in the laminated structure of semiconductor layers 2 through 10 to electrically isolate the HBT 101A, FET 101B and FET 101C.

The semiconductor layers 14 through 21 are sequentially laminated on the n⁺-GaAs lower sub-collector layer and cap layer 13 in the HBT 101A. The characteristics such as the composition and film thickness of the semiconductor substrate 14 through 21 are as follows. 14: n⁺-InGaP etching stopper layer with a film thickness of 20 nm and doping of 1.0×10¹⁹ cm⁻³ silicon impurities, 15: n⁺-InGaAs upper sub-collector layer of a film thickness of 850 nm and doping of 4.0×10¹⁸ cm⁻³ silicon impurities, 16: n-InGaP etching stopper layer with a film thickness of 20 nm and doping of 4.0×10¹⁸ cm⁻³ silicon impurities, 17: n-GaAs collector layer with a film thickness of 800 nm and doping of 1.0×10¹⁶ cm⁻³ silicon impurities, 18: p⁺-GaAs base layer with a film thickness of 80 nm and doping of 4.0×10¹⁹ cm⁻³ carbon impurities, 19: n-InGaP emitter layer with a film thickness of 30 nm and doping of 4.0×10¹⁷ cm⁻³ silicon impurities, 20: n-GaAs emitter ballast layer with a film thickness of 100 nm and doping of 3.0×10¹⁷ cm⁻³ silicon impurities, 21: n⁺-InGaAs emitter contact layer with a film thickness of 100 nm and doping of 2.0×10¹⁹ cm⁻³ selenium impurities.

The sub-collector layer in the HBT 101A is a laminated structure comprised of a lower sub-collector layer and cap layer 13, and an etching stopper layer 14, and an upper sub-collector layer 15. By forming an etching stopper layer within the sub-collector layer, the etching of the upper sub-collector layer 15, and the etching of the laminated structure containing the lower sub-collector and cap layer 13/cap layer 12 can be performed separately in the manufacturing process for the semiconductor device 101.

The sub-collector layer comprised of a laminated structure containing a lower sub-collector layer and cap layer 13, etching stopper layer 14, and upper sub-collector layer 15 possesses a larger forming area than the upper collector layer 17, and a pair of collector electrodes 28 is formed over the section projecting from the collector layer 17 in the sub-collector layer.

In the manufacturing process for the semiconductor device 101, an etching stopper layer 16 is formed between the sub-collector layer and upper collector layer 17 in order to form a sub-collector layer in a pattern projecting from the collector layer 17 to prevent etching of the semiconductor layers 17 through 19.

The laminated structure containing the emitter ballast layer 20 and the emitter contact layer 21 is separated into two regions enclosing the recess (reference number omitted), and an emitter electrode 30 is formed over each of these regions. Moreover, a base electrode 29 contacting the upper layer of the base layer 18 is formed within the recess (reference numeral omitted) formed in the laminated structure containing the emitter ballast layer 20 and the emitter contact layer 21.

In the FET 101B, the laminated structure containing the cap layers 12, 13 is separated into two regions enclosing a recess (reference numeral omitted). The ohmic electrodes 23, 24 are respectively formed over each region. The ohmic electrode 23 is a source electrode and the ohmic electrode 24 is a drain electrode. Moreover, a recess (reference numeral omitted) is formed over the Schottky layer 10. A gate electrode 22 is formed to protrude from this recess within the recess formed in the laminated structure containing the cap layers 12, 13.

In the FET 101C, the laminated structure containing the cap layers 12, 13 is separated into two regions enclosing a recess (reference numeral omitted). The ohmic electrodes 26, 27 are respectively formed over each region. The ohmic electrode 26 is a source electrode and the ohmic electrode 27 is a drain electrode. Moreover, a gate electrode 25 is formed over the Schottky layer 10 within the recess formed in the laminated structure containing the cap layers 12, 13. The semiconductor 101 is therefore configured as related in the above description.

The method for manufacturing the semiconductor device 101 is described next while referring to the drawings in FIGS. 2A-2H. The semiconductor layers (epitaxial layers) 2 through 21 are first of all laminated in sequence over the semiconductor GaAs substrate 1 to obtain the epitaxial wafer shown in FIG. 2A. The WSi film for forming the emitter electrode 30 is next deposited by sputtering across the entire surface of the epitaxial wafer, and using photoresist as a mask the WSi film is then etched to form the emitter electrode 30. Next, the InGaAs emitter contact layer 21 and the GaAs emitter ballast layer 20 are etched utilizing the emitter electrode 30 as a mask, and along with forming a recess over the laminated structure containing the semiconductor layers 20 through 21, the surface of the InGaP emitter layer 19 outside the region formed for the emitter electrode 30 is then exposed. The structure shown in FIG. 2B is in this way obtained after completing the above processes.

The Pt—Ti—Pt—Au film for forming the base electrode 29 is next formed as a pattern over the emitter layer 19 by the evaporation lift-off method using the photoresist as a mask, and the electrode metal diffused by heat treatment into the upper layer section of the emitter layer 19 and the p⁺-GaAs base layer 18 to form the base electrode 29. Then, the n-InGaP emitter layer 19, the p⁺-GaAs base layer 18, the n-GaAs collector layer 17, and the n⁺-InGaP stopper layer 16 are etched using the photoresist as a mask to expose portions of the surface of the n⁺-GaAs lower sub-collector layer 15. The structure shown in FIG. 2C is in this way obtained after completing the above processes.

Next, the n⁺-GaAs sub-collector layer 15 and the n⁺-InGaP stopper layer 14 are etched using the photoresist as a mask, to expose portions of the n⁺-GaAs lower sub-collector layer 13 surface. The structure shown in FIG. 2D is in this way obtained after completing the above process. The n⁺-GaAs lower sub-collector layer 13, the n-GaAs cap layer 12, and the InGaP stopper layer 11 are next etched using the photoresist as a mask, to expose portions of the AlGaAs Schottky layer 10 surface. The structure shown in FIG. 2E is in this way obtained after completing the above process.

The inter-element insulation region 31 is next formed by injection of boron ion using the photoresist as a mask. The structure shown in FIG. 2F is in this way obtained after completing the above process.

Next, the AuGe—Ni—Au ohmic metal forming the collector 28 of the HBT 101A, and the source electrodes 23, 26 of the FET 101B and FET 101C and drain electrodes 23, 27, is pattern-formed over the n⁺-GaAs upper sub-collector layer 15, and the n⁺-GaAs lower sub-collector 13 by the evaporation lift-off method using the photoresist as a mask and then alloyed to form ohmic contact with the lower layer. The structure shown in FIG. 2G is in this way obtained after completing the above processes.

The photoresist of the gate electrode forming section over the FET 101B is next formed in an aperture pattern (gate electrode as an inverted pattern), and this pattern is then utilized as a mask to form a recess by etching the AlGaAs Schottky layer 10 and the InGaP stopper layer 9. That same mask is next utilized to form the gate electrode 22 in this recess by forming a pattern with the evaporation lift-off method. Next, photoresist on the gate electrode forming section over the FET 101C is next formed in an aperture pattern and, this mask is then utilized to form the gate electrode 25 by forming a pattern with the evaporation lift-off method. The structure of the semiconductor 101 shown in FIG. 2H is in this way obtained after completing the above processes.

In the semiconductor device 101 of this embodiment, the sub-collector layer below the collector electrode 28 of HBT 101A is a laminated structure containing a n⁺-GaAs upper sub-collector layer 15 (film thickness 850 nm)/n⁺-InGaP etching stopper layer 14 (film thickness 20 nm)/n⁺-GaAs lower sub-collector layer 13 (film thickness 150 nm); and the total film thickness of this structure is set to 1020 nm.

In this embodiment, the cap layers of the FET 101B, 101C are a laminated structure containing a n⁺-GaAs layer 13 (film thickness 150 nm)/n-GaAs layer 12 (film thickness 50 nm). The lower sub-collector layer 13 of the HBT 101A also serves as a portion of the cap layer for the FET 101B, 101C. The applicable structure jointly uses semiconductor layers among the HBT/FET so that a low cost epitaxial wafer can be achieved.

If the total film thickness of the cap layers for the FET 101B, 101C is too thick, then the etching precision deteriorates when forming the gate recess. Therefore, in the present embodiment the lower sub-collector layer 13 also serving as a portion of the FET 101B, 101C cap layer has a sufficient thickness as an FET cap layer and the range when forming the FET gate recess is set within a range (specifically, a film thickness of 150 nm) so as not to affect the etching precision. The total film thickness of the FET 101B, 101C cap layer is also set to 200 nm.

In order to make the total film thickness of the sub-collector layer thicker in the HBT 101A, the upper sub-collector layer 15 not serving as a portion of the cap layer of the FET 101B, 101C is set to a comparatively thick dimension. In this embodiment, the upper sub-collector layer 15 is made thicker than the lower sub-collector layer 13 and is made a film thickness of 850 nm. In this embodiment, an n⁺-InGaP etching stopper layer 14 is formed within the sub-collector layer so even if the sub-collector layer is made thicker overall by thickening the upper sub-collector layer 15, the etching can be separated into etching above and below the etching stopper layer 14 so that the etching on the sub-collector layer will be precise.

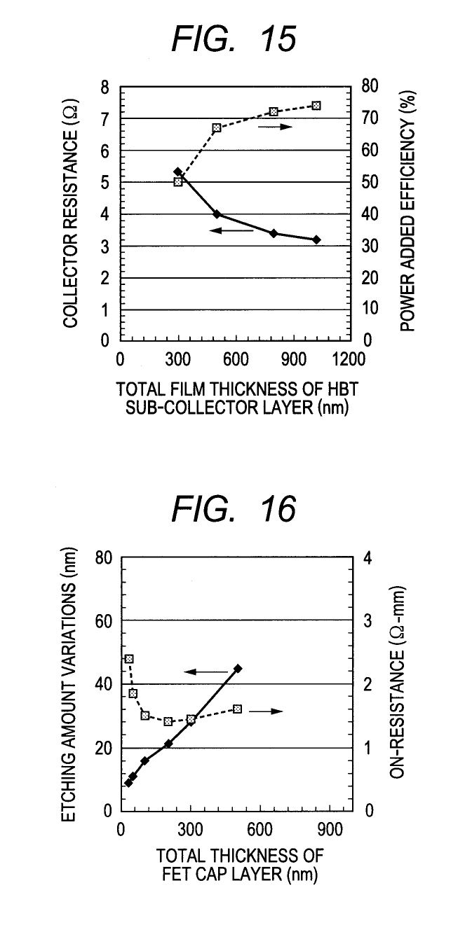

Table 1 and FIG. 15 show results from measuring the collector resistance and the power added efficiency (PAE) of the power amplifier when the inventors changed the total film thickness of the HBT sub-collector layer while keeping all other conditions the same. In these measurements, the film thickness of the lower sub-collector layer 13 was fixed at 150 nm while changing the film thickness of the upper sub-collector layer 15 to change the overall thickness of the sub-collector layer.

Table 1 and FIG. 15 show that the thicker the total film thickness of the sub-collector layer below the collector electrode 28, the lower the collector resistance, and the higher the PAE factor when the power amplifier is operating. A thicker total film thickness for the sub-collector layer below the collector electrode 28 allows a larger cross sectional area on the collector current path 32 that flows laterally within the sub-collector layer, and acts to lower the collector resistance. The sub-collector layer below the collector electrode 28 therefore preferably has a thicker total film thickness. The total film thickness for the sub-collector layer below the collector electrode 28 is set at 500 nm or more and more preferably at 800 nm or more. In the data shown in Table 1, the collector resistance is 4.0 ohm or less at a total film thickness of 500 nm or more in the sub-collector layer below the collector electrode 28; and the collector resistance is 3.4 ohm or less at a total film thickness of 800 nm or higher in the sub-collector layer below the collector electrode 28.

In the BiFET device disclosed in Japanese patent laid-open No. 2009-224407 in the paragraph describing the “BACKGROUND”, the thickness of the sub-collector layer below the collector electrode is preferably 50 to 300 nm. As shown in Table 1, the collector resistance in present embodiment with a sub-collector layer thickness below the collector electrode of 1020 nm is 40 percent lower or more compared to the Japanese patent laid-open No. 2009-224407 whose sub-collector layer thickness below the collector layer electrode is 300 nm or less.

Table 2 and FIG. 16 show results from measuring the FET ON-resistance (Ron) and variations in FET gate recess etching for different FET cap layer thicknesses. In these measurements, the film thickness of the HBT lower sub-collector layer also serving as FET cap layer 13 was changed to change the overall cap layer film thickness while the FET cap layer 12 film thickness was fixed at 50 nm, and the HBT upper sub-collector layer 15 film thickness was fixed at 850 nm. Table 2 and FIG. 16 show that as the total film thickness of the cap layer increases, the etching precision of the FET gate recess deteriorates and that variations on the etched wall surface of the FET gate recess increase. As is also shown in Table 2 and in FIG. 16, the FET ON-resistance increases when the total thickness of the cap layer decreases. Variations within the degree of etching on the wall surface of the FET gate recess are preferably 30 nm or less; and the FET ON-resistance is preferably 2.0 ohm-mm or less so that in order to obtain satisfactory etching precision on the FET gate recess, and to lower the FET ON-resistance, the overall film thickness of the FET cap layer is between 50 nm and 300 nm.

In this embodiment, a cap layer thinner than the HBT sub-collector layer is formed below the FET ohmic electrode. Making the cap layer thicker contributes to increasing the cross sectional area of the lateral flowing drain current path within the cap layer but does not contribute to increasing the cross sectional area of the vertically flowing drain current path 33. A cap layer with a total film thickness of 50 to 300 nm will therefore adequately lower the ON-resistance without worsening the etching variations.

As shown in Table 2, a cap layer with a total film thickness of 200 nm in this embodiment provides satisfactory etching precision with gate recess etching variations of 21 nm (±10.5 nm). Moreover, the FET ON-resistance is 1.40 ohm-mm. However in the cap layer in patent documents 1 and 2 having a total film thickness of 300 to 350 nm, the same variations are 28 nm (±14 nm). Therefore the same variations within the cap layer of this embodiment having a total film thickness of 200 nm are 75% of the same variations within the patent documents 1 and 2. A total film thickness between 50 nm and 200 nm is therefore preferable for the FET cap layer.

In this embodiment, the n-doped impurity concentration within the sub-collector layer of the HBT 101A is set as follows. The silicon impurity concentration of the lower sub-collector layer 13 is 4.0×10¹⁸ cm⁻³, the silicon impurity concentration of the etching stopper layer 14 is 1.0×10¹⁹ cm⁻³, the silicon impurity concentration of the upper sub-collector layer 15 is 4.0×10¹⁸ cm⁻³. The n-type impurity concentration in these layers is not limited to the above description and can be changed as convenient. However the n-type impurity concentration of the etching stopper layer 14 is preferably the same or higher than the n-type impurity concentration of the other semiconductor layers 13, 15 in the sub-collector layer. Moreover, the average concentration of n-type impurities with the sub-collector overall is preferably 2.0×10¹⁸ cm⁻³ or more in order to attain low-resistance ohmic contact with the collector electrode 28, as well as low resistance laterally along the collector current path 32 without depleting the sub-collector layer.

The present embodiment as described above is therefore capable of providing a stable semiconductor device with the HBT and FET both formed on the same substrate, improved HBT characteristics with lowered HBT collector resistance and also satisfactory FET gate recess etching precision, along with low FET ON-resistance.

### Second Embodiment

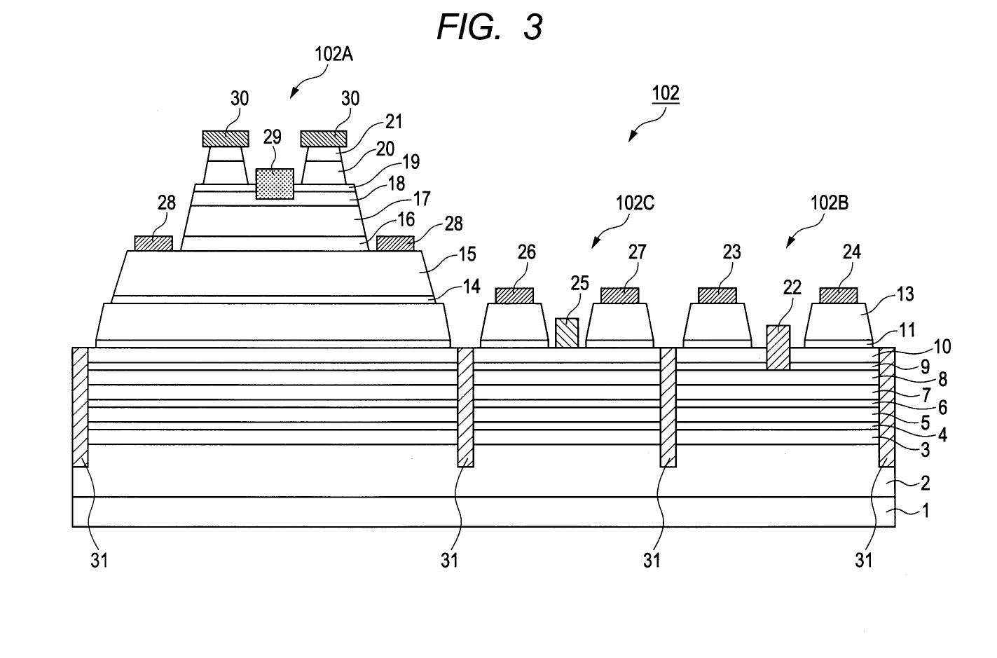

The structure of the semiconductor device of the second embodiment of this invention is described next while referring to FIG. 3. Structural elements identical to the first embodiment are assigned the same reference numerals and their description is omitted.

A semiconductor device 102 of the present embodiment is a BiFET device comprised of one heterojunction bipolar transistor (HBT) 102A, and two field effect transistors (FET) 102B and 102C possessing different threshold voltages and formed in different regions over the same semiconductor substrate 1 the same as in the first embodiment. In this embodiment also, the FET 102B is an E-FET (enhancement-mode FET) and the FET 102C is a D-FET (depletion-mode FET).

The basic structure of the semiconductor device 102 in this embodiment is the same as in the first embodiment. In contrast to the first embodiment in which the FET cap layer is a two-layer laminated structure containing an n-GaAS layer 12 and an n⁺-GaAs layer 13, in the present embodiment the FET 102B and 102C cap layers are an ohmic cap layer comprised of a single-layer structure of n⁺-GaAs layer 13. In the present embodiment the n⁺-GaAs layer 13 is a film thickness of 200 nm. The total film thickness of the cap layer is the same as the first embodiment.

In this embodiment, the total film thickness of the HBT 102A sub-collector layer is 1020 nm, and the total film thickness of the FET 102B, 102C cap layer is 200 nm. This embodiment is therefore also capable of providing a stable semiconductor device with the HBT and FET both formed over the same substrate, improved HBT characteristics with lowered HBT collector resistance and also satisfactory FET gate recess etching precision, along with low FET ON-resistance the same as in the first embodiment.

Besides the above described effects, the semiconductor device 102 of the present embodiment renders the further effect that the ON-resistance in the FET 102B, 102C is lower than in the first embodiment because the total film thickness of the FET cap layer is set to the same conditions as the first embodiment and the n impurity concentration is higher in the entire cap layer in the n⁺-GaAs layer 13 and also in the n-GaAs layer 12 section. In the embodiment example measured by the inventors, the FET 102B, 102C ON-resistance while on was 1.20 ohm-mm.

### Third Embodiment

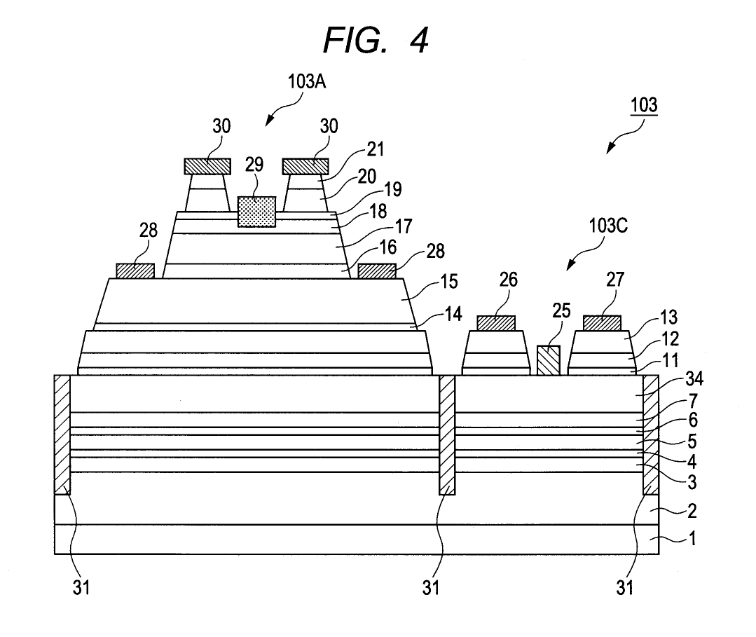

The structure of the semiconductor device of the third embodiment of the present invention is described next while referring to FIG. 4. Structural elements identical to the first embodiment are assigned the same reference numerals and their description is omitted.

A semiconductor device 103 of this embodiment is a BiFET device comprised of one heterojunction bipolar transistor HBT 103A, and one field effect transistor FET 103C formed in different regions over the same semiconductor substrate 1. In this embodiment the FET 103C is a D-FET.

Other than the fact that there is no E-FET, the basic structure of the present embodiment is the same as the first embodiment. The InGaP stopper layer 9 required for forming the E-FET gate recess is now unnecessary. Therefore, instead of the InGaP stopper layer 9, and the undoped AlGaAs Schottky layers 8 and 10 formed above and below the stopper layer 9 in the first embodiment, the present embodiment contains an undoped AlGaAs Schottky layer 34 formed to combine these film thicknesses

This embodiment is therefore also capable of providing a stable semiconductor device with the HBT and FET both formed over the same substrate, improved HBT characteristics with lowered HBT collector resistance and also satisfactory FET gate recess etching precision, along with low ON-resistance in the FET, the same as in the first embodiment. Besides the above described effects, the InGaP stopper layer 9 is no longer needed, and the number of semiconductor layers is reduced in the epitaxial wafer so that the further effect is rendered that the semiconductor device can be manufactured at a lower cost than in the first embodiment.

### Fourth Embodiment

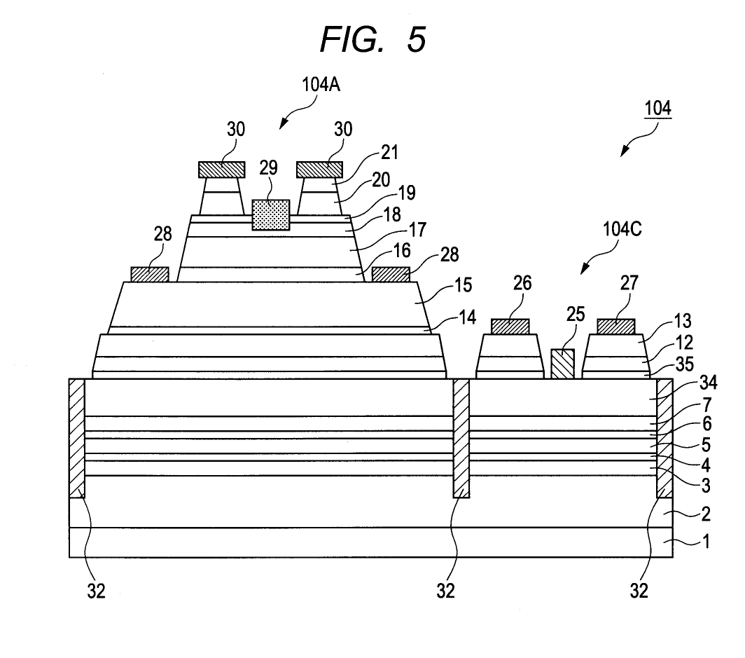

The structure of the semiconductor device of the fourth embodiment of this invention is described next while referring to FIG. 5. Structural elements identical to the third embodiment are assigned the same reference numerals and their description is omitted.

A semiconductor device 104 of the present embodiment is a BiFET device comprised of one heterojunction bipolar transistor HBT 104A, and one field effect transistor FET 104C formed in different regions on the same semiconductor substrate 1 the same as in the first embodiment. In this embodiment also, the FET 104C is a D-FET. In the third embodiment, an InGaP stopper layer 11 as an undoped layer was utilized in order to form a gate recess on the D-FET 103C; however, an n⁺-InGaP layer including a high concentration doping of silicon impurities may also be utilized. The semiconductor device 104 of this embodiment is the same basic structure as the third embodiment. An n⁺-InGaP stopper layer 35 (film thickness 15 nm) with a silicon impurity doping of 1.0×10¹⁹ cm⁻³ is utilized instead of the undoped InGaP stopper layer 11.

This embodiment is therefore also capable of providing a stable semiconductor device with the HBT and FET both formed over the same substrate, improved HBT characteristics with lowered HBT collector resistance and also satisfactory FET gate recess etching precision, along with low ON-resistance in the FET, the same as in the first embodiment. Besides the above described effects, the access resistance from the cap layers 12, 13 to the channel layer 5 is reduced in the FET 104C; rendering the effect that the FET ON-resistance is reduced even further. In the embodiment example measured by the inventors, the access resistance while on was 1.10 ohm-mm.

### Fifth Embodiment

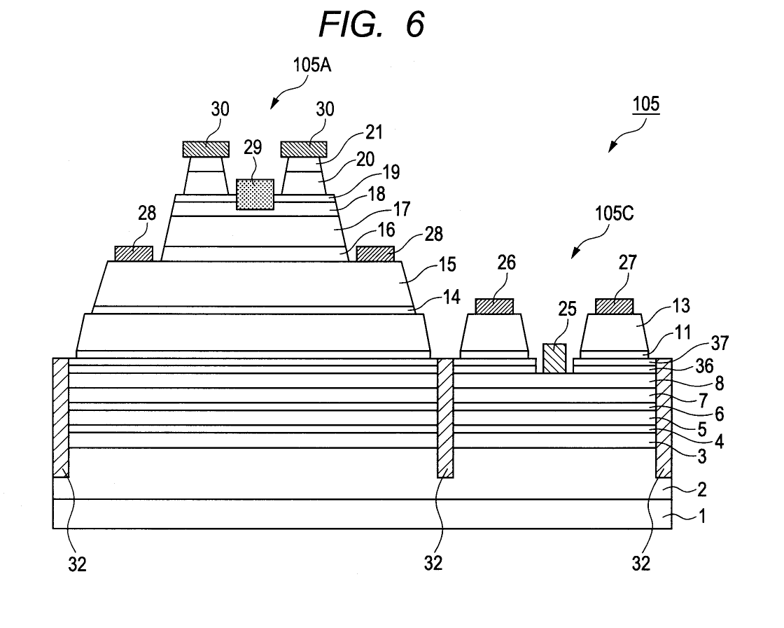

The structure of the semiconductor device of the fifth embodiment of this invention is described next while referring to FIG. 6. Structural elements identical to the first embodiment are assigned the same reference numerals and their description is omitted.

A semiconductor device 105 of the present embodiment is a BiFET device comprised of one heterojunction bipolar transistor HBT 105A and one field effect transistor FET 105C formed over different regions on the same semiconductor substrate 1 the same as in the first embodiment. In this embodiment also, the FET 105C is a D-FET. In this embodiment the cap layer of the FET 105C is an ohmic cap layer comprised of a single layer structure which is an n⁺-GaAs layer 13 (film thickness 200 nm) the same as in the second embodiment. Otherwise the basic structure is the same as the third embodiment. In the gate electrode 25 of the FET 103C in the third embodiment, the bottom surface of a recess is formed with the cap layer removed. In the present embodiment however, a narrow recess is further formed within the same recess, and a gate electrode 25 is formed within that narrow recess. In the present embodiment, an undoped InGaP etching stopper layer 36 and an undoped GaAs layer 37 are formed between the undoped AlGaAs Schottky layer 8 and the undoped InGaP etching stopper 11. Also in this embodiment, the forming section for the gate electrode and that neighboring photoresist pattern are set as the mask, and the InGaP layer 36 utilized as the stopper layer to etch the undoped GaAS layer 37, and then etch the InGaP stopper layer 36 by utilizing this same photoresist as a mask to form the narrow recess.

This embodiment is also capable of providing a stable semiconductor device with the HBT and FET both formed over the same substrate, improved HBT characteristics with lowered HBT collector resistance and also satisfactory FET gate recess etching precision, along with low ON-resistance in the FET the same as in the first embodiment.

### Sixth-Ninth Embodiments

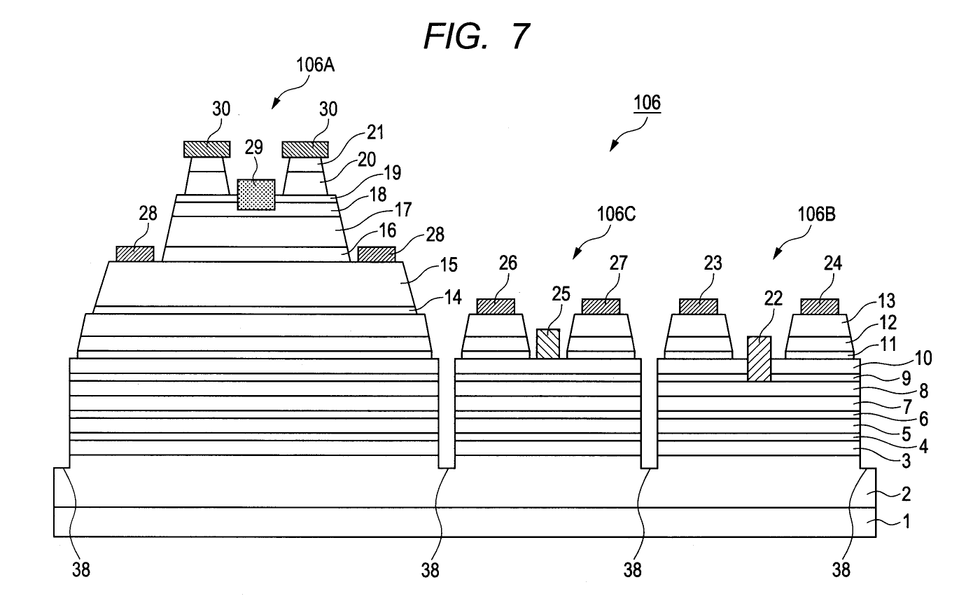

The structures of the semiconductor device of the sixth through ninth embodiments of this invention are described next while referring to FIG. 7 through FIG. 10. Structural elements identical to the first embodiment are assigned the same reference numerals and their description is omitted. In the first through the fifth embodiments, boron ions are injected into a region where the FET cap layer was removed in order to isolate the HBT and FET devices (or elements) by forming an insulating region. However the insulating region may be formed by element isolation methods other than ion injection or by a different injection ion or different ion injection conditions.

A semiconductor device 106 of the sixth embodiment shown in FIG. 7 is a BiFET device comprised of one heterojunction bipolar transistor HBT 106A and two field effect transistors FET 106B and 106C possessing different threshold voltages and formed in different regions over the same semiconductor substrate 1 the same as in the first embodiment. In this embodiment also, the FET 106B is an E-FET and the FET 106C is a D-FET.

The basic structure of this embodiment is the same as the first embodiment, however, a mesa 38 is formed by etching to remove the semiconductor layers from the Schottky layer 10 to the upper section of the buffer layer between the HBT 106A, HBT 106B, and HBT 106C elements in order to isolate the elements.

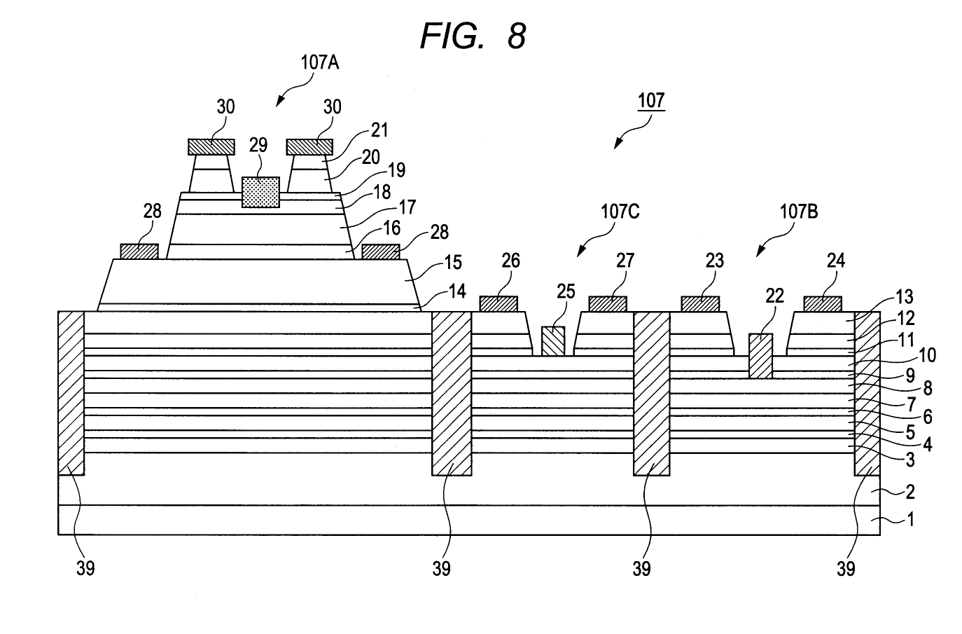

A semiconductor device 107 of the seventh embodiment shown in FIG. 8 is a BiFET device comprised of one heterojunction bipolar transistor HBT 107A and two field effect transistors FET 107B and FET 107C possessing different threshold voltages and formed in different regions over the same semiconductor substrate 1 the same as in the first embodiment. In this embodiment also, the FET 107B is an E-FET and the FET 107C is a D-FET. The basic structure of this embodiment is the same as the first embodiment however in this embodiment no etching is performed on the cap layers 12, 13 between the HBT 107A, FET 107B, and FET 107C elements, and boron ions are injected from that surface to isolate the elements by forming an insulating region 39. By injecting ions under higher energy conditions than the ion injection conditions in the first embodiment, the insulating region 39 can be deeply formed, and the insulating region 39 can be formed to the upper layer of the buffer layer 2 the same as in the first embodiment.

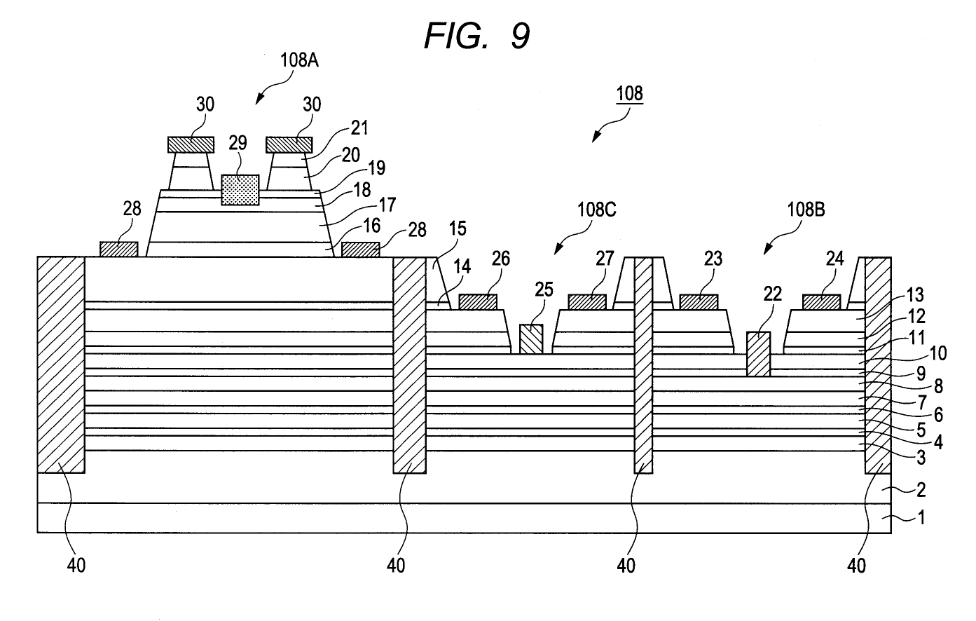

A semiconductor device 108 of the eighth embodiment shown in FIG. 9 is a BiFET device comprised of one heterojunction bipolar transistor HBT 108A and two field effect transistors FET 108B and 108C possessing different threshold voltages and formed in different regions over the same semiconductor substrate 1 the same as in the first embodiment. In this embodiment also, the FET 108B is an E-FET and the FET 108C is a D-FET. The basic structure of this embodiment is the same as the first embodiment however in this embodiment the upper sub-collector layer 15 between the HBT 108A, FET 108B, and FET 108C elements is not etched away, but the elements are isolated by injecting helium ions from that surface to form the isolating region 40. By utilizing helium ions that have a lighter mass than the ion type utilized in the first embodiment, the insulating region 40 can be made deeper, and the insulating region 40 can be formed up to the upper layer section of the buffer layer 2 the same as in the first embodiment.

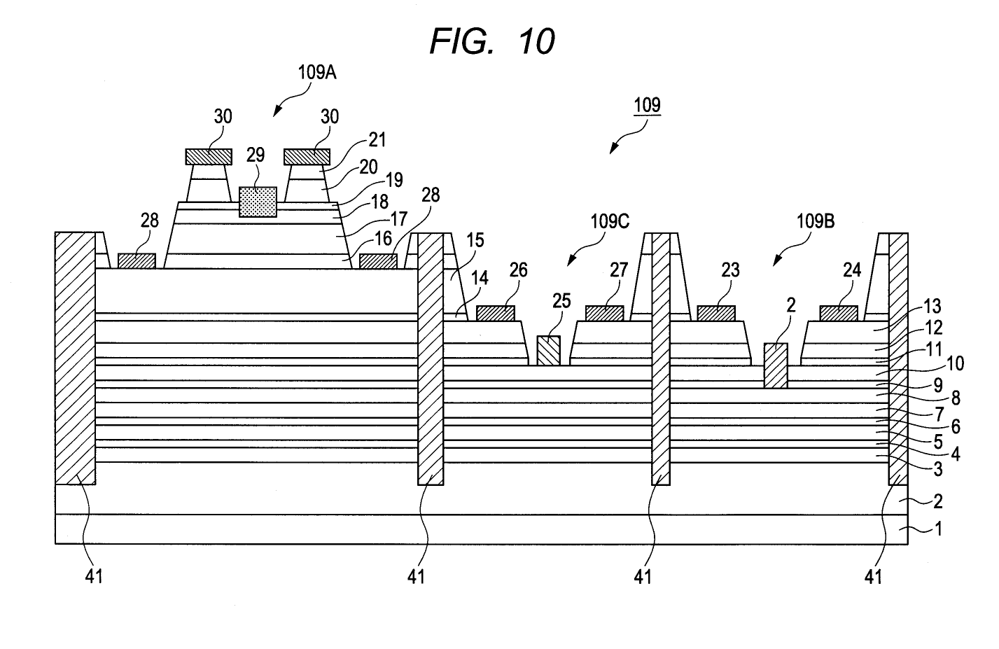

A semiconductor device 109 of the ninth embodiment shown in FIG. 10 is a BiFET device comprised of one heterojunction bipolar transistor HBT 109A and two field effect transistors FET 109B and 109C possessing different threshold voltages and formed in different regions over the same semiconductor substrate 1 the same as in the first embodiment. In this embodiment also, the FET 109B is an E-FET and the FET 109C is a D-FET.

The basic structure of this embodiment is the same as the first embodiment, however in this embodiment the collector layer 17 is left remaining between the HBT 109A, FET 109B, and FET 109C elements (devices) and helium ions injected from that surface to isolate the elements by forming an insulating region 41. Injecting ions under higher energy conditions than in the eighth embodiment, allows forming a deep insulating region 41, and the insulating region 41 can be formed to the upper layer of the buffer layer 2 the same as in the eighth embodiment.

This sixth through the ninth embodiments also are capable of providing a stable semiconductor device with the HBT and FET both formed over the same substrate, improved HBT characteristics with lowered HBT collector resistance and also satisfactory FET gate recess etching precision along with low ON-resistance in the FET the same as in the first embodiment.

### Tenth Embodiment

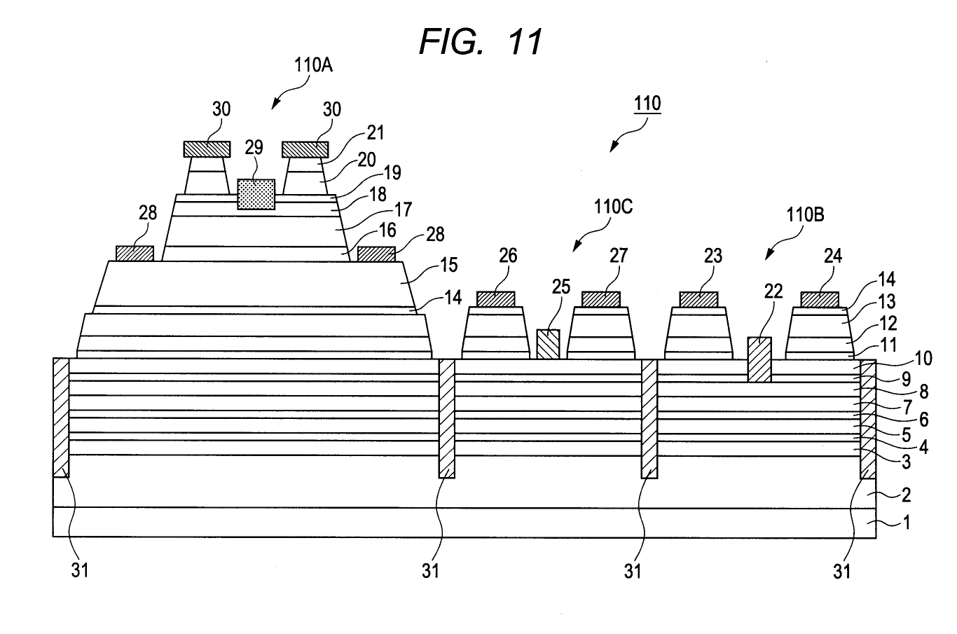

The structure of the semiconductor device of the tenth embodiment of this invention is described next while referring to FIG. 11. Structural elements identical to the first embodiment are assigned the same reference numerals and their description is omitted.

A semiconductor device 110 of this embodiment is a BiFET device comprised of one heterojunction bipolar transistor HBT 110A and two field effect transistors FET 110B and FET 110C possessing different threshold voltages and formed in different regions over the same semiconductor substrate 1 the same as in the first embodiment. In this embodiment also, the FET 110B is an E-FET and the FET 110C is a D-FET.

The basic structure of this embodiment is the same as the first embodiment however, in contrast to the first embodiment in which an FET ohmic electrode is mounted over the n⁺-GaAs cap layer 13; in the present embodiment the n⁺-InGaP etch stopper layer 14 is left remaining over the cap layer 13, and the ohmic electrodes 23, 24, 26, 27 are formed over the FET 110B, FET 110C.

This embodiment is also capable of providing a stable semiconductor device with the HBT and FET both formed over the same substrate, improved HBT characteristics with lowered HBT collector resistance and also satisfactory FET gate recess etching precision, along with low ON-resistance in the FET the same as in the first embodiment. Moreover, compared to the GaAs layer, the InGaP layer has a high n-impurity concentration and moreover has a low Schottky barrier so that contact resistance with the ohmic electrodes can be reduced. Consequently, the present embodiment has lower FET ON-resistance than the first embodiment.

### Eleventh Embodiment

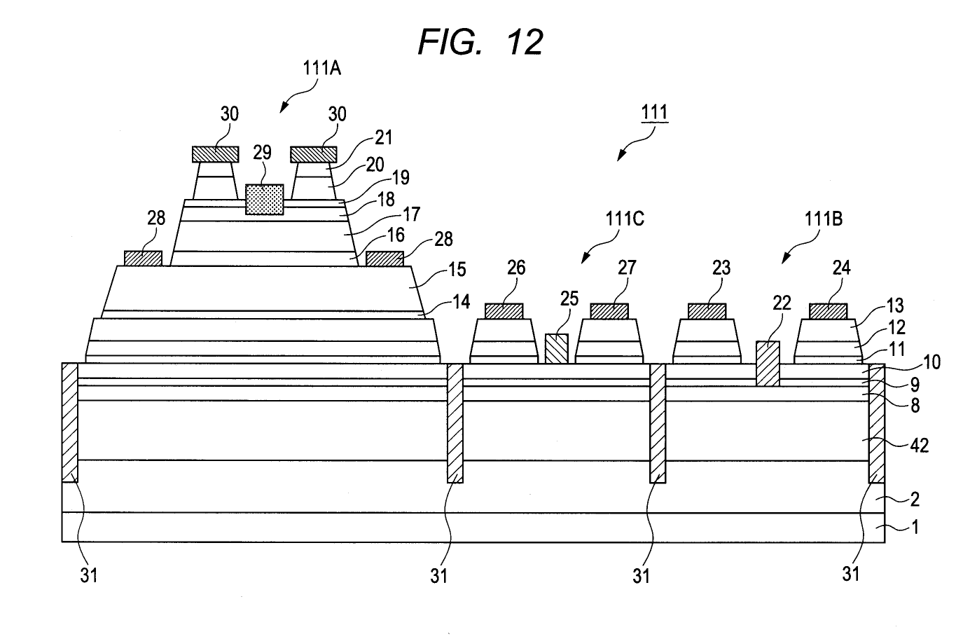

The structure of the semiconductor device of the eleventh embodiment of this invention is described next while referring to FIG. 12. Structural elements identical to the first embodiment are assigned the same reference numerals and their description is omitted.

A semiconductor device 111 of this embodiment is a BiFET device comprised of one heterojunction bipolar transistor HBT 111A and two field effect transistors FET 111B and 111C possessing different threshold voltages and formed on different regions over the same semiconductor substrate 1 the same as in the first embodiment. In this embodiment also, the FET 111B is an E-FET and the FET 111C is a D-FET.

In the first through the tenth embodiments, the FET channel structure was a laminated structure of an n⁺-AlGaAs upper electron supply layer 7/undoped AlGaAs spacer layer 6/undoped InGaAs channel layer 5/undoped AlGaAs spacer layer 4/n⁺-AlGaAs lower electron supply layer 3, however another channel structure may be utilized. The basic structure of this embodiment is the same as the first embodiment however the channel structure of the FET 111B, 111C in this embodiment is a single layer structure that is a n-GaAs channel layer 42 (film thickness 50 nm) with an n-impurity doping of 5.0×10¹⁷ cm⁻³.

This embodiment is also capable of providing a stable semiconductor device with the HBT and FET both formed over the same substrate, improved HBT characteristics with lowered HBT collector resistance and also satisfactory FET gate recess etching precision, along with low FET ON-resistance the same as in the first embodiment.

### Twelfth and Thirteenth Embodiments

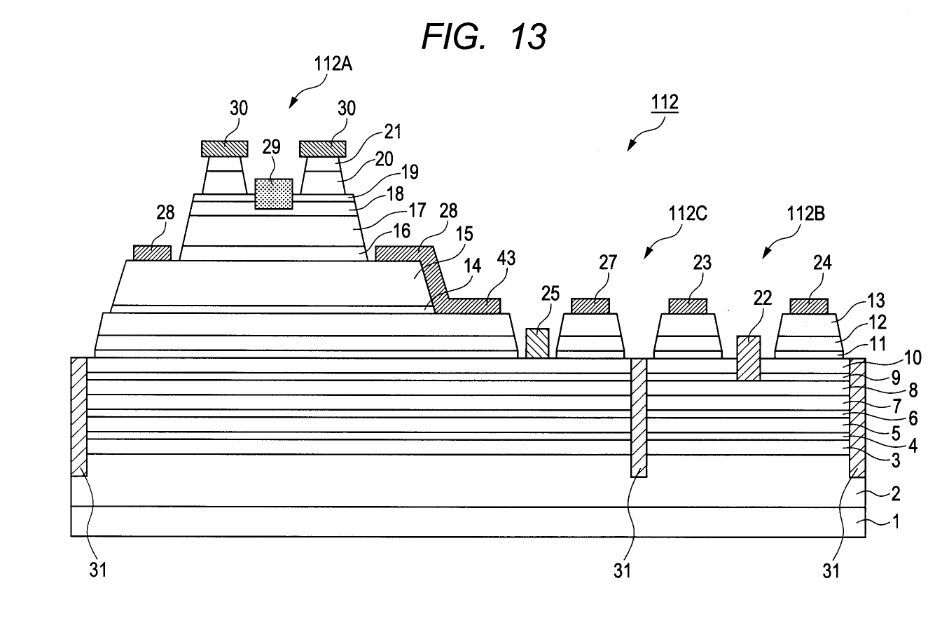

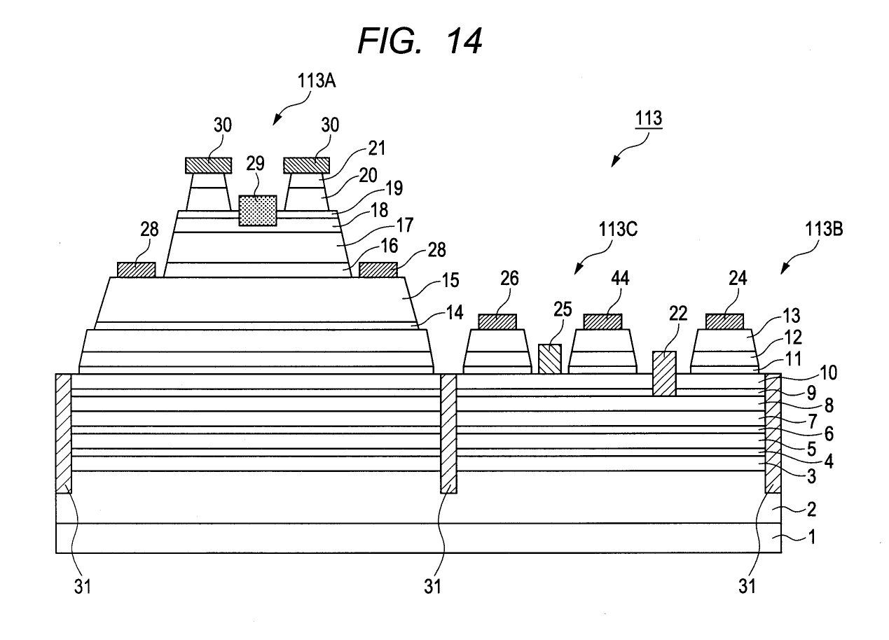

The structure of the semiconductor device of the twelfth and thirteenth embodiments of this invention is described next while referring to FIG. 13 and FIG. 14. Structural elements identical to the first embodiment are assigned the same reference numerals and their description is omitted.

In the first embodiment, the HBT and the two FET elements were isolated by way of an insulating region but two electrodes adjoining the different elements may be jointly used.

A semiconductor device 112 of the twelfth embodiment shown in FIG. 13 is a BiFET device comprised of one heterojunction bipolar transistor HBT 112A and two field effect transistors FET 112B and 112C possessing different threshold voltages and formed in different regions over the same semiconductor substrate 1 the same as in the first embodiment. In this embodiment also, the FET 112B is an E-FET and the FET 112C is a D-FET. The basic structure of this embodiment is the same as the first embodiment however in this embodiment there is no insulating region 31 between the HBT 112A and the FET 112C adjoining that HBT; and one collector electrode 28 of the HBT 112A and the source electrode 26 of the FET 112C are joined together to form the joint ohmic electrode 43.

A semiconductor device 113 of the thirteenth embodiment shown in FIG. 14 is a BiFET device comprised of one heterojunction bipolar transistor HBT 113A and formed from two field effect transistors FET 113B and 113C possessing different threshold voltages and formed in different regions over the same semiconductor substrate 1 the same as in the first embodiment. In this embodiment also, the FET 113B is an E-FET and the FET 113C is a D-FET. The basic structure of this embodiment is the same as the first embodiment however there is no insulating region 31 between the E-FET 113B and the D-FET 113C, and the source electrode 23 of the E-FET 113B and drain electrode 27 of the D-FET 113C together form the joint ohmic electrode 44.

The twelfth and thirteenth embodiments are therefore also capable of providing a stable semiconductor device with the HBT and FET both formed over the same substrate, improved HBT characteristics with lowered HBT collector resistance and also satisfactory FET gate recess etching precision, along with low ON-resistance in the FET the same as in the first embodiment. Moreover in these embodiments the chip can be made in a compact size since the electrodes are jointly shared. Though not shown in the drawings, various patterns can be utilized for joint use of the electrodes. If the same substrate for example contains multiple HBT then one of the collector electrodes of adjacent HBT may be jointly used.

### Design Changes

The present invention is not limited to the above described embodiments and design changes may be made as convenient within a range not deviating from the scope and spirit of the present invention. In the description in the above embodiments for example, a BiFET device utilizing a GaAs substrate served as the semiconductor substrate 1; however, another substrate may be utilized as the semiconductor substrate 1 such as an InP substrate or a GaN substrate. Also in the above embodiments, an n-GaAs layer was the collector layer 17 of the HBT but an undoped layer may be utilized as the collector layer. An n⁺-InGaP layer was utilized as the etching stopper layer 16 formed between the collector layer and the sub-collector layer of the HBT however an undoped layer may be utilized as this etching stopper layer.

TABLE 1

| Total Film Thickness of HBT Sub- | | Collector |
|---|---|---|
| Collector Layer | PAE | Resistance |
| (nm) | (%) | (Ω) |
| 300 | 50 | 5.3 |
| 500 | 67 | 4.0 |
| 800 | 72 | 3.4 |
| 1020 | 74 | 3.2 |

TABLE 2

| Total Film Thickness of FET Cap | | Etching |
|---|---|---|
| layer | Ron | Variations |
| (nm) | (Ωmm) | (nm) |
| 30 | 2.40 | 9 |
| 50 | 1.85 | 11 |
| 100 | 1.50 | 16 |
| 200 | 1.40 | 21 |
| 300 | 1.45 | 28 |
| 500 | 1.60 | 45 |

What is claimed is:

1. A semiconductor device comprising:
over different regions of the same semiconductor substrate,
a heterojunction bipolar transistor including at least a first conductive type sub-collector layer, a collector layer, a second conductive type base layer, a first conductive type emitter layer, a collector electrode, base electrode, and emitter electrode; and
a field effect transistor including a channel layer to accumulate first conductive type carriers, a cap layer, a gate electrode, and a pair of ohmic electrodes formed over the cap layer,
wherein, the sub-collector layer in the heterojunction bipolar transistor includes a laminated structure comprising a plurality of first conductive type semiconductor layers and further the forming surface area of the sub-collector layer is thicker than the collector layer, and in the sub-collector layer, the collector electrode is formed over a section projecting outward from the collector layer,
wherein, in the field effect transistor at least one semiconductor layer among a plurality of first conductive type semiconductor layers on the semiconductor substrate side that form the sub-collector layer of the heterojunction bipolar transistor also serves as at least a portion of the cap layer, and
wherein the total film thickness of the sub-collector layer within the heterojunction bipolar transistor is 500 nm or more, and the total film thickness of the cap layer in the field effect transistor is between 50 nm and 300 nm.

2. The semiconductor device according to claim 1,
wherein the total film thickness of the sub-collector layer within the heterojunction bipolar transistor is 800 nm or more.

3. The semiconductor device according to claim 1,
wherein the total film thickness of the cap layer within the field effect transistor is between 50 nm and 200 nm.

4. The semiconductor device according to claim 1,
wherein the heterojunction bipolar transistor includes an etching stopper layer within the sub-collector layer.

5. The semiconductor device according to claim 4,
wherein the sub-collector layer within the heterojunction bipolar transistor is a laminated structure comprising a lower sub-collector layer also serving as at least a portion of the cap layer within the field effect transistor, an etching stopper layer, and an upper sub-collector layer not serving as at least a portion of the cap layer.

6. The semiconductor device according to claim 5,
wherein the film thickness of the upper sub-collector layer is thicker than the lower sub-collector layer film thickness.

7. The semiconductor device according to claim 4,
wherein,
in the sub-collector layer within the heterojunction bipolar transistor,
the etching stopper layer is an InGaP layer with a first conductive type impurity doping; and
other semiconductor layers within the sub-collector layer are GaAs layers with a first conductive type impurity doping.

8. The semiconductor device according to claim 4,
wherein,
in the sub-collector layer within the heterojunction bipolar transistor,
the first conductive type impurity concentration in the etching stopper layer is the same or higher than the first conductive type impurity concentration in the other semiconductor layers within the sub-collector layer.

9. The semiconductor device according to claim 1,
wherein the average concentration of first conductive type impurity added to the sub-collector layer is 2.0×10¹⁸ cm⁻³ or higher.

10. The semiconductor device according to claim 1,
wherein the heterojunction bipolar transistor contains an etching stopper layer between the sub-collector layer and the collector layer.

11. The semiconductor device according to claim 10,
wherein the etching stopper layer between the sub-collector layer and the collector layer is an InGaP layer with a first conductive type impurity doping or without a first conductive type impurity doping.

12. The semiconductor device according to claim 1,
wherein one collector electrode of the heterojunction bipolar transistor and one of the ohmic electrodes of the field effect transistor are integrated together.

13. The semiconductor device according to claim 1,
wherein a plurality of field effect transistors possessing different threshold voltages are formed over the semiconductor substrate.

14. The semiconductor device according to claim 1,
wherein a plurality of field effect transistors are formed over the semiconductor substrate, and moreover an ohmic electrode of one of the field effect transistors, serves as an ohmic electrode for another field effect transistor.
